(19) United States
(12) Patent Application Publication
(10) Pub. No.: US 2025/0105591 A1
(43) Pub. Date: Mar. 27, 2025

(54) Frequency-Modulated External Cavity Laser Device

(71) Applicant: Suzhou Institute of Nano-Tech and Nano-Bionics (SINANO), CAS, Suzhou (CN)

(72) Inventor: Wei Liang, Suzhou (CN)

(21) Appl. No.: 18/473,487

(22) Filed: Sep. 25, 2023

(51) Int. Cl. H01S 5/14; H01S 5/065; H01S 5/0687

(52) U.S. Cl. CPC H01S 5/141; H01S 5/0657; H01S 5/0687

(57) ABSTRACT

The present invention disclose a frequency-modulated external cavity laser device including a seed light source, a feedback loop external cavity, a light source frequency adjustment module, an FP cavity frequency adjustment module and an external cavity frequency adjustment module. The feedback loop external cavity includes an FP cavity; the light source frequency adjustment module is configured for adjusting an eigenfrequency of the seed light beam; the FP cavity frequency adjustment module is configured for adjusting a resonance frequency of the FP cavity; the external cavity frequency adjustment module is configured for adjusting a resonance frequency of the feedback loop external cavity; and the light source frequency adjustment module, the FP cavity frequency adjustment module and the external cavity frequency adjustment module perform cooperative modulation.

### TECHNICAL FIELD

The present invention relates to laser technology, and more particularly, to a frequency-modulated external cavity laser device.

### BACKGROUND ART

The linewidth of the laser is directly related to the quality of the laser cavity. The quality of the optical cavity of the semiconductor laser is generally low due to the material properties and manufacture process. Frequency-tunable single-frequency narrow-linewidth lasers have important applications in the fields of laser radar, optical frequency-domain reflectometer, quantum and so on. At present, the laser linewidth of the frequency-tunable laser devices is reduced usually by means of the external cavity feedback method. One of the method is to use optical grating to selectively feed a light of certain wavelength so as to return a laser. Another method is to use external reflection mirrors, and in order to avoid the multi-longitudinal mode effect of long optical cavity, a single longitudinal mode is selected by an interference filter. The two types of external cavity lasers described above may achieve frequency modulation by rotating gratings or interference filters. However, due to the low quality of the external cavity, the obtained laser linewidth is typically on the order of tens to hundreds of kilohertz, so that a narrower linewidth may not be obtained.

Currently, although ultra-narrow linewidths may be achieved, various methods to use high Q external cavities of external cavity laser are limited in their fast frequency modulation range to the order of hundreds of megahertz to gigahertz. In the fields such as the frequency-modulated continuous wave laser radar and optical frequency domain reflectometer, the ranging accuracy is inversely proportional to the frequency modulation range. In many quantum application fields, in order to use multiple absorption spectra of atoms, a laser of ultra-narrow linewidth having large frequency modulation range is required. Current laser devices do not meet the requirements of these applications in these fields.

### SUMMARY OF THE INVENTION

The objective of the present invention is to provide a frequency-modulated external cavity laser device to achieve a large-range high-speed continuous frequency-modulated external cavity laser by a high-Q FP optical cavity, and to obtain a larger range of fast continuous frequency modulation and an ultra-narrow linewidth. An embodiment of the present invention provides a frequency-modulated external cavity laser device, comprising a seed light source and a feedback loop external cavity. The feedback loop external cavity comprises an FP cavity, and the cavity length of the FP cavity is less than or equal to 10 cm. The seed light source is configured for outputting a seed light beam. The FP cavity is configured for filtering the seed light beam to form a transmitted light beam. The feedback loop external cavity is configured for feeding back the transmitted light beam to the seed light source to form a feedback light path. The frequency-modulated external cavity laser device further comprises a light source frequency adjustment module, an FP cavity frequency adjustment module and an external cavity frequency adjustment module. The light source frequency adjustment module is configured for adjusting an eigenfrequency f1 of the seed light beam. The FP cavity frequency adjustment module is configured for adjusting a resonance frequency f2 of the FP cavity. The external cavity frequency adjustment module is configured for adjusting a resonance frequency f3 of the feedback loop external cavity. The light source frequency adjustment module, the FP cavity frequency adjustment module and the external cavity frequency adjustment module perform cooperative modulation, so that the eigenfrequency f1 of the seed light beam, the resonance frequency f2 of the FP cavity and the resonance frequency f3 of the feedback loop external cavity satisfy external cavity self-injection locking conditions to form a frequency-locked laser.

In an embodiment, the external cavity self-injection locking condition comprises: a difference between the eigenfrequency f1 of the seed light beam and the resonance frequency f2 of the FP cavity is less than an external cavity self-injection locking range of the feedback loop external cavity; and a difference between the resonance frequency f2 of the FP cavity and the resonance frequency f3 of the feedback loop external cavity is less than or equal to one half of a free spectral range of the feedback loop external cavity.

In an embodiment, the FP cavity frequency adjustment module and the external cavity frequency adjustment module are electrically controlled displacement modules; the electrically controlled displacement modules are respectively mounted on at least one optical component of the feedback loop external cavity and the FP cavity; the electrically controlled displacement module is configured for changing a cavity length of the feedback loop external cavity or the FP cavity, or the electrically controlled displacement module is configured for changing a light path length of a light beam in the optical component so as to adjust a resonance frequency of the feedback loop external cavity or the FP cavity.

In an embodiment, the feedback loop external cavity and the FP cavity respectively comprise at least one reflection unit on which the electrically controlled displacement module is fitted. The electrically controlled displacement module is configured for changing the cavity length of the feedback loop external cavity or the FP cavity according to the formula Δf/f=ΔL/L so as to adjust the resonance frequency of the feedback loop external cavity or the FP cavity. The letter f represents a current resonance frequency of the feedback loop external cavity or the FP cavity; Δf is a variation amount of the resonance frequency of the feedback loop external cavity or the FP cavity; L is a current cavity length of the feedback loop external cavity or the FP cavity; and ΔL is a variation amount of the cavity length of the feedback loop external cavity or the FP cavity.

In an embodiment, the feedback loop external cavity and the FP cavity respectively comprise at least one prism unit, and the electrically controlled displacement module is mounted on the prism unit. The electronically controlled displacement module is configured for changing the light path length of a light beam in the optical component according to the formula Δf/f=n1*ΔL/(n2*L), so as to adjust the resonance frequency of the feedback loop external cavity or the FP cavity. The letter f represents a current resonance frequency of the feedback loop external cavity or the FP cavity; Δf is a variation amount of the resonance frequency of the feedback loop external cavity or the FP cavity; n2*L is a total light path length of the feedback loop external cavity or the FP cavity; and n1*ΔL is a light path length variation amount of the feedback loop external cavity or the FP cavity.

In an embodiment, the FP cavity frequency adjustment module and the external cavity frequency adjustment module are respectively an electrically controlled refractive index module or a thermally controlled refractive index module, and the electrically controlled refractive index module or the thermally controlled refractive index module is respectively located in the feedback loop external cavity or the FP cavity. The electrically controlled refractive index module is configured for changing a refractive index by an electro-optical effect, and the thermally controlled refractive index module is configured for changing a refractive index by a thermo-optical effect, so as to adjust a light path length of a light beam in the electrically controlled refractive index module or the thermally controlled refractive index module, thereby adjusting the resonance frequency of the feedback loop external cavity or the FP cavity.

In an embodiment, the seed light source comprises a first end and a second end; the seed light beam is output from the first end of the seed light source and the transmitted light beam is input from the first end of the seed light source. The feedback loop external cavity further comprises a first collimation unit configured for collimating the seed light beam, a unidirectional transmission unit configured for transmitting the seed light beam to the FP cavity, and blocking a reflection light beam of the FP cavity from being incident on the seed light source and a reflection unit configured for reflecting the transmitted light beam of the FP cavity back to the seed light source to form a feedback light path.

In an embodiment, the first collimation unit comprises a first lens; the unidirectional transmission unit comprises a polarizing beam splitter, a first quarter-wave plate, a second quarter-wave plate and a second lens in sequence; the reflection unit comprises a first reflection mirror. The FP cavity is located between the first quarter-wave plate and the second quarter-wave plate; and the second lens is located between the FP cavity and the second quarter-wave plate or between the second quarter-wave plate and the first reflection mirror.

In an embodiment, the seed light source comprises a first end and a second end; the seed light beam is output from a first end of the seed light source, and the transmitted light beam is input from the first end of the seed light source. Or, the seed light beam is output from the first end of the seed light source, and the transmitted light beam is input from the second end of the seed light source. The feedback loop external cavity further comprises the unidirectional transmission unit and a light ray steering unit; the unidirectional transmission unit is configured for transmitting the seed light beam to the FP cavity, and blocking a reflection light beam of the FP cavity from being incident on the seed light source; and the light ray steering unit is configured for changing the transmission direction of the transmitted light beam of the FP cavity, so that the transmitted light beam is fed back to the seed light source to form a feedback light path.

In an embodiment, the unidirectional transmission unit comprises a circulator, and the light ray steering unit comprises a second reflection mirror, a third reflection mirror and a fourth reflection mirror. The light beam transmission path in the frequency-modulated external cavity laser device includes that the seed light beam is output from a first end of the seed light source, input from a first end of the circulator, output from a second end of the circulator, and is incident on the FP cavity for transmission to form the transmitted light beam; and the transmitted light beam is incident on a third end of the circulator after being reflected by the second reflection mirror, the third reflection mirror and the fourth reflection mirror in sequence, and is output from a first end of the circulator and fed back to the seed light source.

In an embodiment, the unidirectional transmission unit comprises an isolator, and the light ray steering unit comprises a fifth reflection mirror, a sixth reflection mirror, a seventh reflection mirror and an eighth reflection mirror. The light beam transmission path in the frequency-modulated external cavity laser device is as follows: the seed light beam is output from a first end of the seed light source, input from a first end of the isolator, output from a second end of the isolator, and is incident on the FP cavity for transmission to form the transmitted light beam; and the transmitted light beam is incident on a second end of the seed light source after being reflected by the fifth reflection mirror, the sixth reflection mirror, the seventh reflection mirror and the eighth reflection mirror in sequence.

In an embodiment, the unidirectional transmission unit further comprises at least one isolator, at least one of the isolators being located between the seed light source and the FP cavity.

In an embodiment, the FP cavity comprises a ninth reflection mirror and a tenth reflection mirror parallel to each other, and the seed light beam is incident by the ninth reflection mirror and is emergent by the tenth reflection mirror; or the FP cavity comprises an eleventh reflection mirror, a twelfth reflection mirror and a thirteenth reflection mirror; and the seed light beam is incident by the eleventh reflection mirror, reflected by the twelfth reflection mirror and the thirteenth reflection mirror in sequence, and then emergent by the eleventh reflection mirror.

In an embodiment, the seed light source comprises a semiconductor laser; or, the seed light source comprises a combination of a gain chip and an optical filter, the optical filter being located at any position in the feedback loop external cavity.

The embodiments of the present invention provide a the seed light source and the feedback loop external cavity, and provide a short FP cavity with a cavity length less than or equal to two centimeters in the feedback loop external cavity, the seed light beam is emergent by the seed light source, the seed light beam is filtered by the FP cavity with a high Q value to form a transmitted light beam, and the transmitted light beam is fed back by the feedback loop external cavity to the seed light source to form a feedback light path. Thus, a frequency-locked laser with an ultra-narrow linewidth is achieved. In addition, three frequency adjustment modules are also provided in this embodiment, respectively performing cooperative modulation on the frequencies of the three optical cavities to ensure that the frequencies of the three optical cavities satisfy the self-injection locking condition of the external cavity, forming a frequency-locked laser, and achieving ultra-large range and high-speed continuous frequency modulation. The embodiment of the present invention solves the problem of a relatively small frequency modulation range of the existing narrow-line-width laser. By using the short FP cavity with a high Q value to participate in frequency locking of the feedback external cavity, and also performing frequency cooperative modulation on three optical cavities in the frequency-modulated external cavity laser device, the frequency modulation range may be increased to tens to hundreds of GHZ, and a fast and large-range continuous frequency-modulated external cavity narrow linewidth laser may be constructed, so that the frequency-modulated external cavity laser device may improve the ranging accuracy in the fields of frequency modulation continuous wave laser radar, optical frequency domain reflectometer, etc. Meanwhile, for the quantum application field, the frequency-modulated external cavity laser of the present invention may meet the requirements of using multiple atomic absorption spectra. The field of application of laser devices is thus expanded.

### BRIEF DESCRIPTION OF THE DRAWINGS

FIGS. 1 and 2 are simplified structural views of two frequency-modulated external cavity laser devices according to an embodiment of the present invention;

FIGS. 3 and 4 are spectral views of an optical cavity in FIG. 1 and FIG. 2, respectively;

FIG. 5 is a structural view of a further frequency-modulated external cavity laser device according to an embodiment of the present invention;

FIG. 6 is a structural view of a further frequency-modulated external cavity laser device according to an embodiment of the present invention;

FIGS. 7 and 8 are structural views of another two frequency-modulated external cavity laser devices according to an embodiment of the present invention;

FIG. 9 is a structural view of a further frequency-modulated external cavity laser device according to an embodiment of the present invention;

FIG. 10 is a structural view of a further frequency-modulated external cavity laser device according to an embodiment of the present invention.

### DETAILED DESCRIPTION OF THE INVENTION

The terminology used in the examples of the invention herein is for the purpose of describing particular embodiments only and is not intended to be limiting of the invention. It should be noted that the terms “upper”, “lower”, “left”, “right”, and the like in the description of the embodiments of the present invention are used from the angle shown in the accompanying drawings only and are not to be construed as limiting the embodiments of the present invention. In addition in this context, it should also be understood that when an element or is referred to as being formed “on” or “below” another element, it can be directly or indirectly formed “on” or “below” the other element, or it can be indirectly formed “on” or “below” the other element via intervening elements. The terms “first”, “second”, and the like are used for descriptive purposes only and do not represent any order, quantity, or importance, but rather are used to distinguish one component from another. The specific meaning of the above terms in this invention will be understood in specific circumstances by those of ordinary skill in the art.

As described in the background section, various external cavity schemes using a high-Q optical cavity have emerged in recent years, and ultra-narrow linewidth lasers at and below kilohertz can be obtained, for example, using a high-quality factor (Whispering Gallery Mode) echo wall optical cavity as a filter to construct a composite optical cavity. Lasers with linewidths at hundreds of Hertz or even Hertz levels can be realized, but the fast tuning range of the piezoelectric ceramic is only hundreds of MHz. As an alternative, a SOC annular cavity can be used, and the static thermal frequency modulation range thereof can reach 9 GHz, but the rapid frequency modulation of the piezoelectric ceramic is only 1 GHz@12 kHz modulation frequency. In addition, there are also laser solutions using fiber optic cavities or high Q FP cavities, however, the fast frequency modulation range is also small.

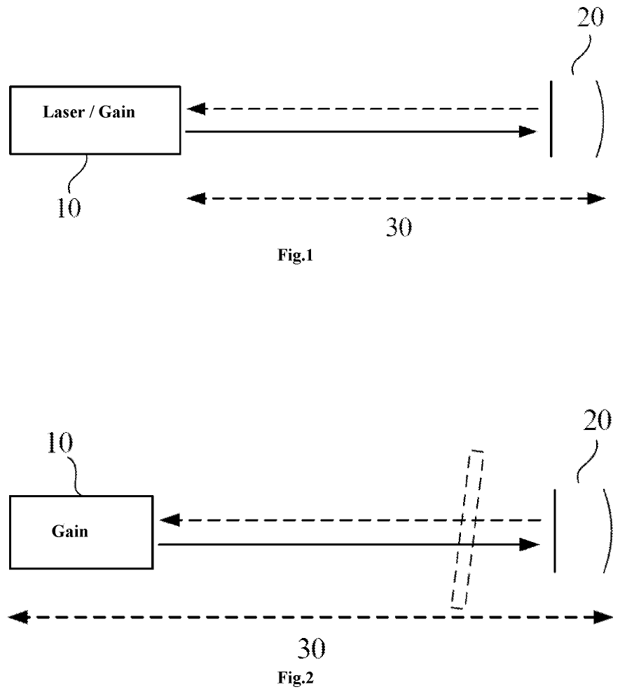

In view of the above, embodiments of the present invention provide a frequency-modulated external cavity laser device. FIGS. 1 and 2 are simplified structural views of two frequency-modulated external cavity laser devices according to an embodiment of the present invention. With reference to FIGS. 1 and 2, the frequency-modulated external cavity laser device includes a seed light source 10 and a feedback loop external cavity 30. The feedback loop external cavity 30 includes an FP cavity 20, and the cavity length of the FP cavity 20 is less than or equal to 10 cm. The seed light source 10 is configured for outputting a seed light beam. The FP cavity 20 is configured for filtering the seed light beam to form a transmitted beam. The feedback loop external cavity 30 is configured for feeding the transmitted light beam back to the seed light source 10 to form a feedback light path.

The frequency-modulated external cavity laser device further includes a light source frequency adjustment module, an external cavity frequency adjustment module and an FP cavity frequency adjustment module (not shown in the figures). The light source frequency adjustment module is configured for adjusting an eigenfrequency f1 of the seed light beam. The external cavity frequency adjustment module is configured for adjusting a resonance frequency f3 of the feedback loop external cavity. The FP cavity frequency adjustment module is configured for adjusting a resonance frequency f2 of the FP cavity. The light source frequency adjustment module, the FP cavity frequency adjustment module and the external cavity frequency adjustment module perform cooperative modulation, so that the eigenfrequency f1 of the seed light beam, the resonance frequency f2 of the FP cavity and the resonance frequency f3 of the feedback loop external cavity satisfy external cavity self-injection locking conditions to form a frequency-locked laser.

The seed light source 10 is, in essence, an optical cavity with a gain, and a semiconductor laser may be selected to generate a seed light beam with a relatively wide linewidth. A combination of a gain chip and a filter may also be used. The gain chip has a relatively high gain for a specific waveband (for example, a C waveband). The optical filter may select a laser wavelength within the gain spectral line range (several tens of nm) of the gain chip. The feedback loop external cavity 30 is used to make the seed light beam form an external cavity self-injection locking. The feedback loop external cavity 30 is essentially an optical cavity with a low Q value, which may reduce the laser linewidth to some extent. The feedback loop external cavity 30 may be a coaxial optical cavity retracing along the primary path or may be a feedback loop formed using a steering assembly, such as an annular feedback loop. However, in the embodiment of the present invention, an FP cavity 20 is provided in the feedback loop external cavity 30. The FP cavity 20 is essentially an optical cavity with a high Q value. The laser filtered and fed back by the FP cavity 20 may form the self-injection locking of the external cavity, and the original linewidth of the laser may be narrowed at the same time.

It should be noted that the cavity length of the FP cavity 20 according to the present invention is less than or equal to 10 cm. Essentially, by means of a short FP cavity, a fast, wide range frequency modulation is achieved by the FP cavity under the premise of using a high Q value to realize an ultra-narrow linewidth laser. Compared with other solid-state optical cavities, the modulation range may be extended by using the short FP cavity. Specially, the modulation range may be increased by several orders of magnitude. For example, when an FP short cavity with a cavity length of 2 mm is used, the cavity mirror reflectivity reaches above 99.992%. When the Q value exceeds 10, one thousandth of the cavity length of the FP cavity may be changed by modulating the cavity length by 2 μm. The optical cavity frequency of about 200 GHz may be changed around 1550 nm (corresponding to an optical frequency of 200 THz). Compared with high-Q external cavity lasers such as a fiber laser, an echo wall optical cavity and an on-chip micro-ring cavity, the optical cavity frequency adjustment range of this embodiment may be increased by 1-2 orders of magnitude. As another example, when the cavity length of the FP cavity is 2 cm, by changing the cavity length of 2 μm, i.e. changing one ten-thousandth of the cavity length, a large range of frequency modulation of 20 GHz@1550 nm may be achieved for frequency adjustment. This may also greatly improve the frequency modulation range compared the existing high-Q external cavity laser.

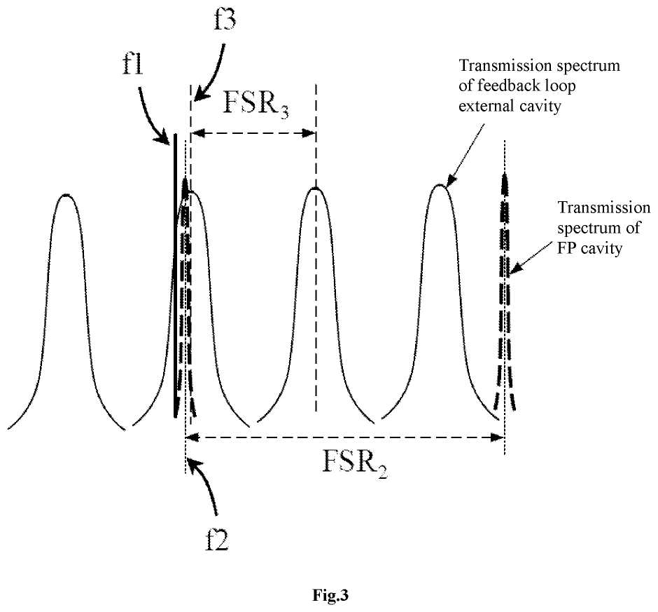

Essentially, in the embodiment of the present invention, a composite external cavity laser is formed by three optical cavities. The necessary condition for forming an effective external cavity self-injection locking is that the frequencies of the three optical cavities must be aligned as much as possible. Therefore, it can be understood that the external cavity laser device of the present embodiment is required to perform cooperative modulation on the three optical cavities during frequency modulation, so as to ensure that the frequencies of the three optical cavities always satisfy the external cavity self-injection locking conditions, thereby dynamically forming a frequency-locked laser. Specifically, in the embodiments of the present invention, a light source frequency adjustment module, an FP cavity frequency adjustment module and an external cavity frequency adjustment module are provided for correspondingly adjusting the frequencies of the three optical cavities synchronously or in an equal proportion so as to ensure the alignment of the frequencies of the three optical cavities. Thus, the external cavity self-injection locking condition may still be satisfied during the dynamic frequency modulation process to form a frequency-locked laser. FIG. 3 and FIG. 4 are spectral views of the optical cavity of FIG. 1 and FIG. 2, respectively. As shown in FIG. 3 and FIG. 4, solid vertical black lines represent the eigenfrequency f1 of the seed light source. The narrower periodic dotted line represents the transmission spectrum of the FP cavity, and the transmission peak frequency thereof close to the eigenfrequency f1 of the seed light source is the resonance frequency f2 of the FP cavity. The wider Lorentz-shaped solid line represents the transmission spectrum of the feedback loop external cavity, whose transmission peak frequency close to the eigenfrequency f1 of the seed light source is the resonance frequency f3 of the feedback loop external cavity. In order to ensure that the three optical cavities form an effective self-injection locking, the eigenfrequency f1 of the seed light source, the transmission peak frequency f2 of the FP cavity and the transmission peak frequency f3 of the feedback loop external cavity are required to be aligned on the frequency spectrum as much as possible. When the frequency modulation of the frequency-modulated external cavity laser device is performed, for example, when the resonance frequency of the FP cavity changes, i.e., the narrow periodic dotted line moves left and right, in order to maintain an effective self-injection locking, the transmission peak frequency f3 of the feedback loop external cavity and the eigenfrequency f1 of the seed light source must both maintain the synchronous movement with the transmission peak frequency f2 of the FP cavity, i.e., it needs to ensure the cooperative modulation of the three optical cavities, so as to avoid the loss of self-injection locking and the occurrence of mode hopping.

In addition, it needs to be noted that three frequency adjustment modules may specifically use the same control device to perform frequency modulation control so as to achieve cooperative modulation of three optical cavities. A person skilled in the art would have been able to design various embodiments according to actual situations. In addition, the three frequency adjustment modules may respectively be additional frequency adjustment structures. For example, with regard to the FP cavity, the corresponding frequency adjustment module thereof may be a piezoelectric ceramic PZT by means of which the resonance frequency may be adjusted by changing the cavity length of the FP cavity, and may also be frequency adjustment components which are provided by the seed light source 10, the feedback loop external cavity 30 and the FP cavity 20 itself. Taking the seed light source 10 as a DFB distributed feedback laser as an example, the seed light source 10 itself has a frequency adjustment component Bragg grating, which may adjust the frequency of the emergent light beam of the distributed feedback laser by changing the current injected via the DFB and using the Bragg grating.

In the embodiments of the present invention, by providing the seed light source and the feedback loop external cavity, and providing a short FP cavity with a cavity length being less than or equal to two centimeters in the feedback loop external cavity, the seed light beam is emergent by the seed light source, the seed light beam is filtered by the FP cavity with a high Q value to form a transmitted light beam, and the transmitted light beam is fed back by the feedback loop external cavity to the seed light source to form a feedback light path. Thus, a frequency-locked laser with an ultra-narrow linewidth is achieved. In addition, three frequency adjustment modules are also provided in this embodiment, respectively performing cooperative modulation on the frequencies of the three optical cavities to ensure that the frequencies of the three optical cavities satisfy the self-injection locking condition of the external cavity, forming a frequency-locked laser, and achieving ultra-large range and high-speed continuous frequency modulation. The embodiment of the present invention solves the problem of a relatively small frequency modulation range of the existing narrow-line-width laser. By using the short FP cavity with a high Q value to participate in frequency locking of the feedback external cavity, and also performing frequency cooperative modulation on three optical cavities in the frequency-modulated external cavity laser device, the frequency modulation range may be increased to tens to hundreds of GHz, and a fast and large-range continuous frequency-modulated external cavity narrow linewidth laser may be constructed, so that the frequency-modulated external cavity laser device may improve the ranging accuracy in the fields of frequency modulation continuous wave laser radar, optical frequency domain reflectometer, etc. Meanwhile, for the quantum application field, the frequency-modulated external cavity laser of the present invention may meet the requirements of using multiple atomic absorption spectra. The field of application of laser devices is thus expanded.

Embodiments of the present invention provide detailed solutions to the specific conditions of frequency cooperative modulation of the three optical cavities described above. With continued reference to FIGS. 1-4, further optional external cavity self-injection locking conditions include that the difference between the eigenfrequency f1 of the seed light beam and the resonance frequency f2 of the FP cavity is less than the external cavity self-injection locking range of the feedback loop external cavity; and the difference between the resonance frequency f2 of the FP cavity and the resonance frequency f3 of the feedback loop external cavity is less than or equal to one half of the free spectral range of the feedback loop external cavity.

Herein, with regard to the resonance frequency f2 of the FP cavity and the resonance frequency f3 of the feedback loop external cavity, it can be seen from the spectrum that the difference therebetween should not exceed half of the free spectral range FSR3 of the feedback loop external cavity. In this case, the resonance frequency f2 is in the free spectral range FSR3 of the feedback loop external cavity, indicating that the resonance frequency f2 of the FP cavity may be substantially aligned with the resonance frequency f3 of the feedback loop external cavity. With regard to the eigenfrequency f1 of the seed light beam and the resonance frequency f2 of the FP cavity, taking a conventional distributed feedback laser chip as an example, under suitable feedback conditions, the self-injection locking range of the external cavity thereof is several hundreds of megahertz to several gigahertz. In order to ensure the self-injection locking, the difference between the eigenfrequency f1 of the seed light beam and the resonance frequency f2 of the FP cavity should be less than the above-mentioned self-injection locking range of the external cavity. At this time, the eigenfrequency f1 of the seed light beam is spectrally located on a position of the spectrum close to the resonance frequency f2. On the basis that the above-mentioned frequencies f1, f2 and f3 may be guaranteed to be close to or in the range of mutual alignment in the frequency spectrum during dynamic frequency modulation, the frequency-locked laser may be formed, and the external cavity self-injection locking condition may be satisfied.

On the basis of the above, the embodiments of the present invention also provide various manners of adjusting the optical cavity frequency. Specifically, and optionally, the FP cavity frequency adjustment module and the external cavity frequency adjustment module are electrically controlled displacement modules. The electrically controlled displacement module is respectively mounted on at least one optical component of the feedback loop external cavity and the FP cavity. The electrically controlled displacement module is configured for changing a cavity length of the feedback loop external cavity or the FP cavity, or the electrically controlled displacement module is configured for changing a light path length of a light beam in the optical component so as to adjust a resonance frequency of the feedback loop external cavity or the FP cavity.

In addition, the FP cavity frequency adjustment module and the external cavity frequency adjustment module are also an electric control refractive index module or a thermal control refractive index module optionally and respectively. The electrically controlled refractive index module or the thermally controlled refractive index module is respectively located in the feedback loop external cavity or the FP cavity. The electrically controlled refractive index module is configured for changing a refractive index by an electro-optical effect, and the thermally controlled refractive index module is configured for changing a refractive index by a thermo-optical effect, so as to adjust a light path length of a light beam in the electrically controlled refractive index module or the thermally controlled refractive index module, thereby adjusting the resonance frequency of the feedback loop external cavity or the FP cavity.

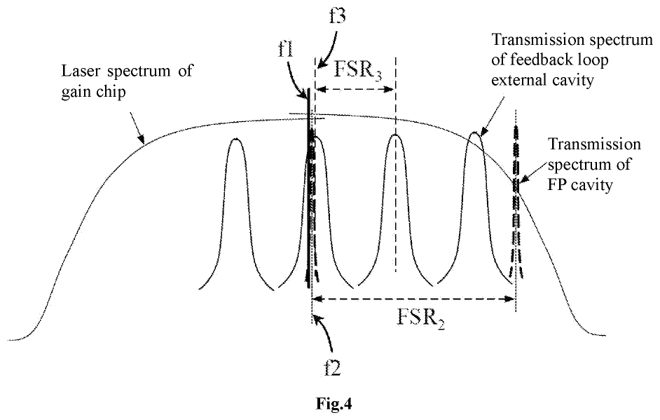

Firstly, a detailed example of the above-mentioned solution for adjusting the optical cavity frequency by the electrically controlled displacement module is introduced. FIG. 5 is a structural view of a further frequency-modulated external cavity laser device provided by an embodiment of the present invention. Referring to FIG. 5, a feedback loop external cavity 30 and an FP cavity 20 respectively include at least one reflection unit, and an electrically controlled displacement module 40 is mounted on the reflection unit. The electrically controlled displacement module 40 is configured for changing the cavity length of the feedback loop external cavity 30 or the FP cavity 20 according to the formula Δf/f=ΔL/L so as to adjust the resonance frequency of the feedback loop external cavity 30 or the FP cavity 20, where f is the current resonance frequency of the feedback loop external cavity 30 or the FP cavity 20, Δf is a variation amount of the resonance frequency of the feedback loop external cavity 30 or the FP cavity 20, L is a current cavity length of the feedback loop external cavity 30 or the FP cavity 20, and ΔL is a variation amount of the cavity length of the feedback loop external cavity 30 or the FP cavity 20.

It should be noted that the solution of the electrically controlled displacement module adjusting the optical cavity frequency may be applied to different composite external cavity laser structures. Taking a composite external cavity laser structure shown in FIG. 5 as an example, in this embodiment, the seed light source 10 includes a first end 1 and a second end 2. A seed light beam is output from the first end 1 of the seed light source 10, and a transmitted light beam is input from the first end 1 of the seed light source 10. The feedback loop external cavity 30 further includes a first collimation unit 31, a unidirectional transmission unit 32 and a reflection unit 33. The first collimation unit 31 is configured for collimating the seed light beam. The unidirectional transmission unit 32 is configured for transmitting the seed light beam to the FP cavity 20, and blocking the reflected light beam of the FP cavity 20 from being incident on the seed light source 10. The reflection unit 33 serves to reflect the transmitted light beam of the FP cavity 20 back to the seed light source 10 to form a feedback light path.

More specifically, it may be provided that the first collimation unit 31 includes a first lens 311. The unidirectional transmission unit 32 includes a polarizing beam splitter 321, a first quarter-wave plate 322, a second quarter-wave plate 323 and a second lens 324 in sequence. The reflection unit 33 includes a first reflection mirror 331. The FP cavity 20 is positioned between the first quarter-wave plate 322 and the second quarter-wave plate 323. The second lens 324 is positioned between the FP cavity 20 and the second quarter-wave plate 323.

The FP cavity may be a hollow FP cavity or a solid FP cavity. The hollow FP cavity may be a parallel cavity, a plano-concave cavity or a concave-concave cavity. Specifically, the FP cavity 20 may be provided to include a ninth reflection mirror 21 and a tenth reflection mirror 22 parallel to each other. The seed light beam is incident from the ninth reflection mirror 21 and emergent from the tenth reflection mirror 22.

In the frequency-modulated external cavity laser device, and in the feedback light path, specifically, the seed light source 10 emits a seed light beam which is collimated by the first lens 311 and then passes through the polarizing beam splitter 321. The polarizing beam splitter 321 transmits a P parallel polarization component of the seed light beam and reflects an S perpendicular polarization component. After passing through the first quarter-wave plate 322, the P parallel polarization component is converted into circular polarization light, which is coupled and emergent by the FP cavity, collimated by the second lens 324, and then transformed into a first line polarization light by the second quarter-wave plate 323, the first line polarization light is perpendicular to the polarization direction of the above-mentioned P parallel polarization component. The first linear polarization light is reflected by the first reflection mirror 331, then transformed into the circular polarization light by the second quarter-wave plate 323, and is transformed into second linear polarization by the first quarter-wave plate 322 after passing through the FP cavity. The second linear polarization light is in the same polarization direction as the above-mentioned P parallel polarization component. At this time, the second linear polarization light may be transmitted through the polarizing beam splitter 321 and finally fed back to the seed light source 10 via the first lens 311.

It should be noted that in this embodiment the polarizing beam splitter 321, the first quarter-wave plate 322, the second quarter-wave plate 323 and the second lens 324 essentially constitute a unidirectional transmission unit 32, which may be used to block the light beam reflected by the FP cavity while ensuring that the light beam in the feedback loop external cavity returns on the same axis as the original path. Specifically, it will be appreciated that the circular polarization light transformed from the first quarter-wave plate 322, as it passes through the FP cavity 20, forms reflected light on the reflective structure in the FP cavity 20 towards the seed light source 10. It would affect the self-injection locking of the entire external cavity if the reflected light enters directly into the seed light source 10. In the structure of this embodiment, the first quarter-wave plate 322 and the polarizing beam splitter 321 are arranged so that the reflected light passing through the first quarter-wave plate 322 forms a third linear polarization light perpendicular to the polarization direction of the above-mentioned P-parallel polarization component. The third linear polarization light is reflected when passing through the polarizing beam splitter 321 and may not be transmitted through the polarizing beam splitter 321, thereby effectively blocking the reflected light formed by the FP cavity from being fed back to the seed light source.

In this embodiment, the electrically controlled displacement module 40 corresponding to the feedback loop external cavity 30 is a first electrically controlled displacement module 41, as shown in the figure, which may be mounted on the back face of the reflection unit 33, i.e., the first reflection mirror 331, but may also be mounted on the side surface or front surface of the first reflection mirror 331, etc. The electrically controlled displacement module 40 may particularly be a piezoceramic PZT or a voice coil motor or the like. It will be understood by those skilled in the art that, under the control of an electrical signal, the piezoelectric ceramic PZT or voice coil motor may precisely move the position of the reflection unit 33 so as to adjust the cavity length of the feedback loop external cavity 30. In other words, the resonance frequency f3 of the feedback loop external cavity 30 may be adjusted by changing the cavity length by means of the first electrically controlled displacement module 41. Similarly, with regard to the FP cavity 20, the corresponding electrically controlled displacement module 40 thereof is a second electrically controlled displacement module 42, which specifically may also be a piezoelectric ceramic PZT or a voice coil motor, etc. As shown in the figure, a second electrically controlled displacement module 42 may be provided on the back face of the tenth reflection mirror 22, may also be mounted on the side or front side of the tenth reflection mirror 22, etc. The resonance frequency f2 of the FP cavity 20 may be adjusted by precisely moving the position of the tenth reflection mirror 22 via the piezoelectric ceramic PZT or the voice coil motor.

The electrically controlled displacement module 40 in this embodiment is primarily responsible for moving the position of a component of the optical cavity so as to adjust the cavity length of the optical cavity using the cavity length to change the frequency of the optical cavity. Therefore, when adjusting the cavity length of the optical cavity, it is necessary to ensure the frequency cooperative modulation of the three optical cavities. Specifically, the cavity length of the feedback loop external cavity 30 or the FP cavity 20 may be changed according to the ratio of the cavity length variation amount to the current cavity length being equal to the ratio of the frequency variation amount to the current frequency, so as to guide the adjustment of the resonance frequency of the feedback loop external cavity 30 or the FP cavity 20.

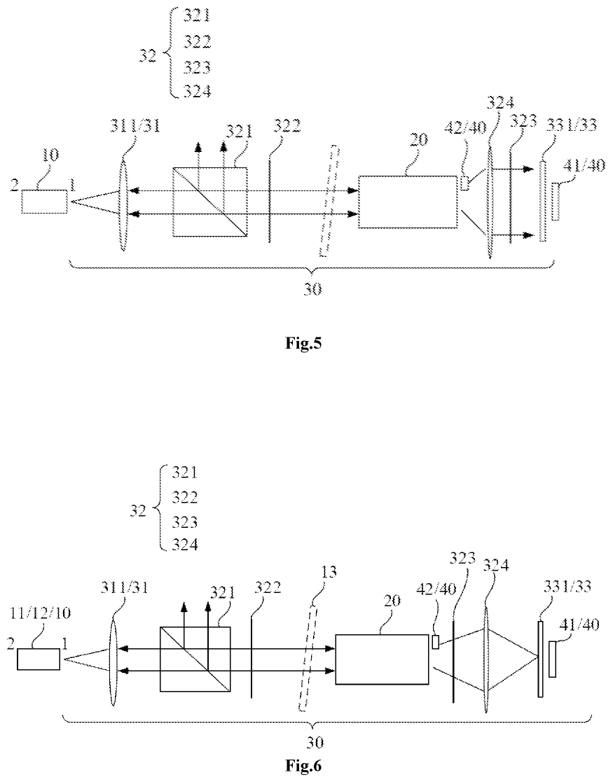

FIG. 6 is a structural view of a further frequency-modulated external cavity laser device according to an embodiment of the present invention. Comparing FIG. 5 and FIG. 6, an second lens 324 in an optional unidirectional transmission unit 32 is positioned between a second quarter-wave plate 323 and a first reflection mirror 331. Here, the frequency-modulated external cavity laser device as shown in FIG. 6 is substantially a variation of FIG. 5. In the structure of the laser device as shown in FIG. 6, the transmitted light of the FP cavity 20 is converged to the first reflection mirror 331 through the second lens 324, thereby reducing the accuracy and difficulty of the angular alignment of the first reflection mirror 331.

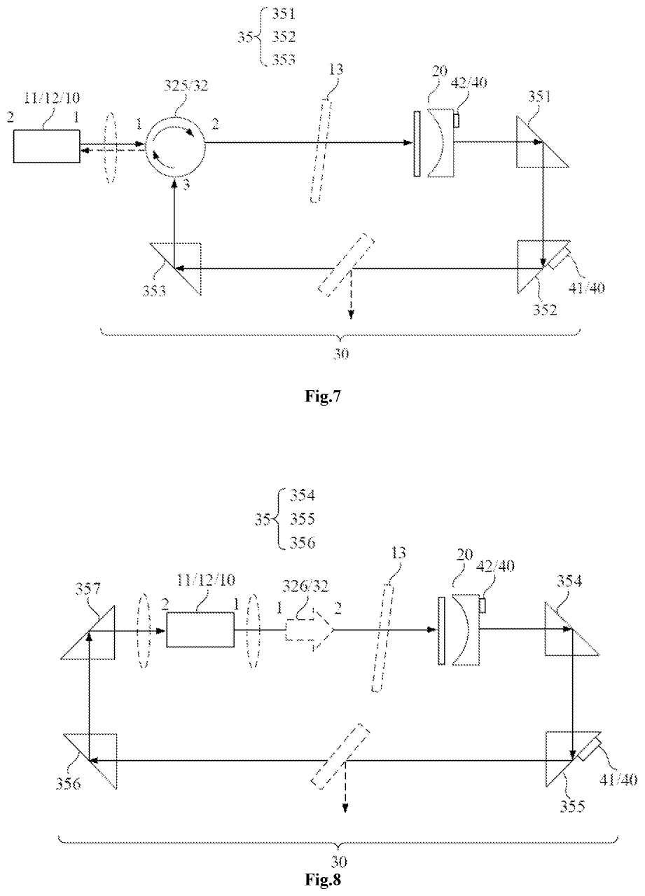

The other composite external cavity laser structures are also provided by embodiments of the present invention which adjust the optical cavity frequency for the electrically controlled displacement modules. FIGS. 7 and 8 are structural views of another two frequency-modulated external cavity laser devices according to an embodiment of the present invention. Referring to FIGS. 7 and 8, a seed light source 10 includes a first end 1 and a second end 2. A seed light beam is output from the first end 1 of the seed light source 10, and a transmitted light beam is input from the first end 1 of the seed light source 10. Alternatively, the seed light beam is output from the first end 1 of the seed light source 10, and the transmitted light beam is input from the second end 2 of the seed light source 10. The feedback loop external cavity 30 further includes a unidirectional transmission unit 32 and a light ray steering unit 35. The unidirectional transmission unit 32 is configured for transmitting the seed light beam to the FP cavity 20, and blocking the reflected light beam of the FP cavity 20 from being incident on the seed light source 10. The light ray steering unit 35 is configured for changing the transmission direction of the transmitted light beam of the FP cavity 20, so that the transmitted light beam is fed back to the seed light source 10 to form a feedback light path.

Specifically, referring to FIG. 7, in this embodiment, a seed light beam is output from the first end 1 of the seed light source 10 and a transmitted light beam is input from the first end 1 of the seed light source 10. The unidirectional transmission unit 32 includes a circulator 325. The light ray steering unit 35 includes a second reflection mirror 351, a third reflection mirror 352, and a fourth reflection mirror 353. According to the beam transmission path in the FM external cavity laser device, the seed light beam is output from the first end 1 of the seed light source 10, input from the first end 1 of the circulator 325, output from the second end 2 of the circulator 325, and is incident on the FP cavity 20 for transmission to form a transmitted light beam. The transmitted light beam is incident on the third end 3 of the circulator 325 after being reflected by the second reflection mirror 351, the third reflection mirror 352 and the fourth reflection mirror 353 in sequence, and is output from the first end 1 of the circulator 325 and fed back to the seed light source 10.

Referring to FIG. 8, in this embodiment, the seed light beam is output from the first end 1 of the seed light source 10 and the transmitted light beam is input from the second end 2 of the seed light source 10. The unidirectional transmission unit 32 includes an isolator 326. The light ray steering unit 35 includes a fifth reflection mirror 354, a sixth reflection mirror 355, a seventh reflection mirror 356, and an eighth reflection mirror 357. According to the beam transmission path in the FM external cavity laser device, the seed light beam is output from the first end 1 of the seed light source 10, input by a first end 1 of the isolator 326, output by a second end 2 of the isolator, and is incident on the FP cavity for transmission to form a transmitted light beam. The transmitted light beam is incident on the second end 2 of the seed light source 10 after being reflected by the fifth reflection mirror 354, the sixth reflection mirror 355, the seventh reflection mirror 356 and the eighth reflection mirror 357 in sequence.

In the two embodiments shown in FIGS. 7 and 8, the first electrically controlled displacement module 41 corresponding to the feedback loop external cavity 30 may be mounted on the back face of any reflection mirror in the light ray steering unit 35. The cavity length of the feedback loop external cavity 30 may be changed by adjusting the position of the reflection mirror, thereby adjusting the frequency of the light cavity. With regard to the FP cavity 20, the second electrically controlled displacement module 42 may be provided on the back face of the tenth reflection mirror 22. The resonance frequency f2 of the FP cavity 20 may be adjusted by precisely moving the position of the tenth reflection mirror 22 via the piezoelectric ceramic PZT or the voice coil motor.

Furthermore, with regard to the composite external cavity laser structure provided in the four embodiments of FIGS. 5-8, a person skilled in the art would have optionally added at least one isolator in the above-mentioned unidirectional transmission unit, the isolator being located between the seed light source and the FP cavity. At this time, the isolator may further block the reflected light of the FP cavity, effectively reducing the influence of the direct reflected light of the FP cavity on the frequency locking of the whole external cavity.

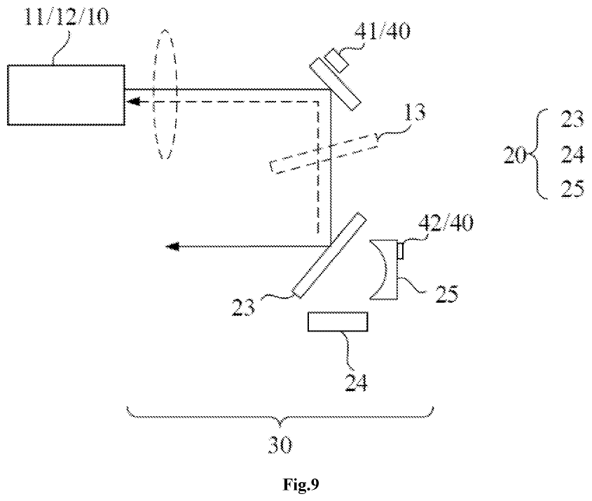

FIG. 9 is a structural view of a further frequency-modulated external cavity laser device according to an embodiment of the present invention. Referring to FIG. 9, this embodiment provides another embodiment for the structure of the FP cavity. As shown in FIG. 9, the FP cavity 20 may include an eleventh reflection mirror 23, a twelfth reflection mirror 24, and a thirteenth reflection mirror 25. The seed light beam is incident from the eleventh reflection mirror 23, reflected by the twelfth reflection mirror 24 and the thirteenth reflection mirror 25, and then emergent from the eleventh reflection mirror 23.

In this embodiment, the FP cavity 20 is essentially an annular FP cavity consisting of a three-sided high reflection mirror. The cavity length modulation of the ring-shaped FP cavity is achieved by a piezoceramic PZT on a one-sided cavity mirror. The seed light beam is reflected and coupled into the annular FP cavity 20 via a reflection mirror provided in the feedback loop external cavity. After passing through the eleventh reflector 23, the seed light beam is reflected by the twelfth reflector 24, the eleventh reflector 23, the thirteenth reflector 25, the eleventh reflector 23 and the twelfth reflector 24 in sequence, and then emergent from the twelfth reflector 23 to form a transmitted beam. The transmission beam returns to the seed light source 10 along the original path. The cavity length of the feedback loop external cavity is achieved by placing a piezoceramic PZT on the reflection mirror therein, which will not be described further herein.

In the frequency-modulated external cavity laser device of each of the above-mentioned embodiments, in addition to the deformation of the feedback loop external cavity and the FP cavity, the seed light source may also be implemented in different ways. Taking the embodiment shown in FIGS. 5-9 as an example, the optional seed light source 10 is a semiconductor laser 11. Alternatively, the seed light source 10 may include a combination of a gain chip 12 and an optical filter 13. The optical filter 13 may be placed at any position in the feedback loop external cavity 30.

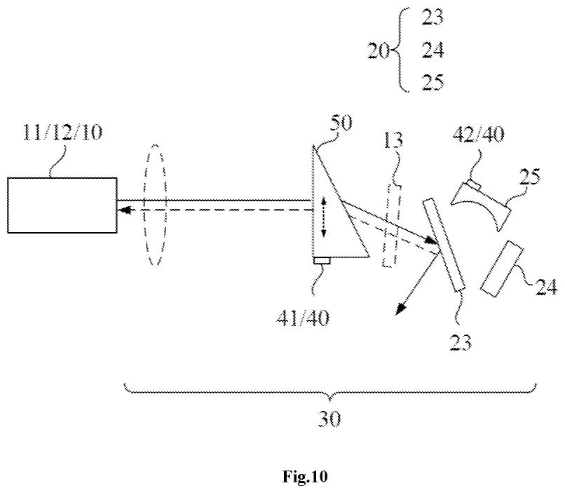

In addition, a person skilled in the art would have been able to understand that the frequency-locked laser of each of the above-mentioned frequency-modulated external cavity laser devices has different light output modes. As shown in FIGS. 5 and 6, the frequency-locked laser may be reflected upwards by a polarizing beam splitter 321. As shown in FIGS. 9 and 10, the frequency-locked laser may be output by a ring-shaped FP cavity 20. For the laser device shown in FIG. 7, a beam splitter may be optionally provided in the light path between the third reflection mirror 352 and the fourth reflection mirror 353. The frequency-locked laser may be output by using the beam splitter. Similarly, for the laser device shown in FIG. 8, the beam splitter may be optionally provided in the light path between the sixth reflection mirror 355 and the seventh reflection mirror 356. The frequency-locked laser is output by the beam splitter.

In other embodiments of the present invention, the optical cavity frequency adjustment may also be achieved on different principles using an electrically controlled displacement module. FIG. 10 is a structural view of a further frequency-modulated external cavity laser device according to an embodiment of the present invention. With reference to FIG. 10, in this embodiment, the feedback loop external cavity 30 and/or the FP cavity 20 respectively include at least one prism unit 50, and the electrically controlled displacement module 40 is mounted on the prism unit 50. The electrically controlled displacement module 40 is used to change the light path length of the light beam in the optical component to adjust the resonance frequency of the feedback loop external cavity 30 or the FP cavity 20 according to the formula Δf/f=n1*ΔL/(n2*L). At this time, f is a current resonance frequency of the feedback loop external cavity or FP cavity. Δf is a variation amount of the resonance frequency of the feedback loop external cavity or FP cavity. n2*L is a total light path length of the feedback loop external cavity or FP cavity. n1*ΔL is a light path length variation amount of the feedback loop external cavity or FP cavity.

Herein, a prism unit 50 is provided in the feedback loop external cavity 30 and/or the FP cavity 20, so that there is a part of the light path length of the seed light beam in the prism unit 50. Since the prism unit 50 has a certain refractive index n1, the position of the prism unit 50 may be adjusted by an electrically controlled displacement module 40 such as a piezoelectric ceramic PZT or a voice coil motor. Conversely, the relative position of the beam in the prism unit 50 may be adjusted, so that the light path length of the light beam in the prism unit 50 may be changed. Here, the light path length in the prism unit 50 may be expressed by n1*L. The stroke L of light in the prism unit 50 and the light path length n1*L may be changed when the prism unit 50 moves in the direction perpendicular to the light beam. In this embodiment, the cavity length of the feedback loop external cavity 30 or the FP cavity 20 may also be changed according to the ratio of the light path length variation amount to the current light path length being equal to the ratio of the frequency variation amount to the current frequency so as to guide the adjustment of the resonance frequency of the feedback loop external cavity 30 or the FP cavity 20. The electrically controlled displacement module 40 may be mounted on a side of the prism unit 50 as shown in the figure. A person skilled in the art may arrange same at any other position according to practical designs, without being limited thereto.

It should be noted that the structure of the FP cavity and the feedback loop external cavity as shown in FIG. 10 is only one embodiment thereof. A person skilled in the art would be able to make reasonable modifications to the FP cavity and the feedback loop external cavity with reference to the composite external cavity structure shown in FIGS. 5-9, and the description thereof will not be repeated here. It should also be noted that since the light path length of the optical cavity has a linear relationship with the phase in nature (θ=2πL/λ), using the light path length as an adjustment factor in the above-mentioned embodiment is merely one expression. A person skilled in the art may understand that the phase of the optical cavity may also be adjusted via the above-mentioned prism unit and the electrically controlled displacement module. Therefore, on the basis of the above-mentioned embodiments, a person skilled in the art would have a design to adjust the frequency of the optical cavity by changing the phase, which is essentially the same as the adjustment of the frequency of the optical cavity by changing the light path length in the embodiments of the present invention. This is a reasonable variation on the basis of the above-mentioned embodiments, and thus does not depart from the scope of the present invention.

Based on the above-mentioned embodiments of the prism unit and the electrically controlled displacement module, a person skilled in the art would understand that the light path change of the optical cavity depends not only on a stroke L of a light beam in the optical component, but also on the refractive index n of the optical component. Based on this, in an embodiment of the present invention, by means of an electro-optical effect or a thermo-optical effect, an electrically controlled refractive index module and a thermally controlled refractive index module are respectively provided in the feedback loop external cavity or the FP cavity. The light path length may be changed by the electrically controlled refractive index module or the thermally controlled refractive index module by changing the refractive index so as to adjust the resonance frequency of the feedback loop external cavity and the FP cavity. It can be understood that the composite external cavity structure provided in each of the above-mentioned embodiments may also be applied to the solution of adjusting the frequency of the optical cavity by the electrically controlled refractive index module or the thermally controlled refractive index module, which can be designed by a person skilled in the art according to actual situations and is not exemplified herein.

It is noted that the foregoing is only a preferred embodiment of the preferred embodiment of the present invention and the technical principles applied thereto. It will be understood by those skilled in the art that the present invention is not limited to the particular embodiments described herein, and that various obvious changes, rearrangements, combinations and substitutions will occur to those skilled in the art without departing from the scope of the present invention. Therefore, while the invention has been described in considerable detail with reference to the above embodiments, the invention is not limited to the above embodiments. It is intended to cover various other equivalent embodiments without departing from the spirit of the invention, the scope of which is defined by the appended claims.

What is claimed is:

1. A frequency-modulated external cavity laser device comprising:
a seed light source configured for outputting a seed light beam;
a feedback loop external cavity including an FP cavity configured for filtering the seed light beam to form a transmitted light beam, the cavity length of the FP cavity being less than or equal to 10 cm, wherein the feedback loop external cavity is configured for feeding back the transmitted light beam to the seed light source to form a feedback light path, said feedback loop external cavity;
a light source frequency adjustment module configured for adjusting an eigenfrequency f1 of the seed light beam;
an FP cavity frequency adjustment module configured for adjusting a resonance frequency f2 of the FP cavity; and
an external cavity frequency adjustment module configured for adjusting a resonance frequency f3 of the feedback loop external cavity;
wherein the light source frequency adjustment module, the FP cavity frequency adjustment module and the external cavity frequency adjustment module perform cooperative modulation, so that the eigenfrequency f1 of the seed light beam, the resonance frequency f2 of the FP cavity and the resonance frequency f3 of the feedback loop external cavity satisfy external cavity self-injection locking conditions to form a frequency-locked laser.

2. The frequency-modulated external cavity laser device according to claim 1, wherein the external cavity self-injection locking conditions comprises:
a difference between the eigenfrequency f1 of the seed light beam and the resonance frequency f2 of the FP cavity is less than an external cavity self-injection locking range of the feedback loop external cavity; and
the difference between the resonance frequency f2 of the FP cavity and the resonance frequency f3 of the feedback loop external cavity is less than or equal to one half of a free spectral range of the feedback loop external cavity.

3. The frequency-modulated external cavity laser device according to claim 1, wherein the FP cavity frequency adjustment module and the external cavity frequency adjustment module are electrically controlled displacement modules which are respectively mounted on feedback loop external cavity and at least one optical component of the FP cavity;
the electrically controlled displacement module is configured for changing a cavity length of the feedback loop external cavity or the cavity length of the FP cavity, or the electrically controlled displacement module is configured for changing a light path length of a light beam in the optical component so as to adjust a resonance frequency of the feedback loop external cavity or a resonance frequency of the FP cavity.

4. The frequency-modulated external cavity laser device according to claim 3, wherein the feedback loop external cavity and the FP cavity respectively comprise at least one reflection unit, and the electrically controlled displacement module is mounted on the reflection unit;
the electrically controlled displacement module is configured for changing the cavity length of the feedback loop external cavity or the FP cavity according to the formula Δf/f=ΔL/L so as to adjust the resonance frequency of the feedback loop external cavity or the FP cavity; and
wherein f is a current resonance frequency of the feedback loop external cavity or the FP cavity; Δf is a variation amount of the resonance frequency of the feedback loop external cavity or the FP cavity; L is a current cavity length of the feedback loop external cavity or the FP cavity; and ΔL is a variation amount of the cavity length of the feedback loop external cavity or the FP cavity.

5. The frequency-modulated external cavity laser device according to claim 3, wherein the feedback loop external cavity and the FP cavity respectively comprise at least one prism unit, and the electrically controlled displacement module is mounted on the prism unit;
the electrically controlled displacement module is configured for changing the light path length of a light beam in the optical component according to the formula Δf/f=n1*ΔL/(n2*L), so as to adjust the resonance frequency of the feedback loop external cavity or the FP cavity;
wherein f is a current resonance frequency of the feedback loop external cavity or the FP cavity; Δf is a variation amount of the resonance frequency of the feedback loop external cavity or the FP cavity; n2*L is a total light path length of the feedback loop external cavity or the FP cavity; and n1*ΔL is a light path length variation amount of the feedback loop external cavity or the FP cavity.

6. The frequency-modulated external cavity laser device according to claim 1, wherein the FP cavity frequency adjustment module and the external cavity frequency adjustment module are respectively an electrically controlled refractive index module or a thermally controlled refractive index module; the electrically controlled refractive index module or the thermally controlled refractive index module is respectively located in the feedback loop external cavity or the FP cavity; and
the electrically controlled refractive index module is configured for changing a refractive index by an electro-optical effect, and the thermally controlled refractive index module is configured for changing a refractive index by a thermo-optical effect, so as to adjust a light path length of a light beam in the electrically controlled refractive index module or the thermally controlled refractive index module, thereby adjusting the resonance frequency of the feedback loop external cavity or the FP cavity.

7. The frequency-modulated external cavity laser device according to claim 1, wherein the seed light source comprises a first end and a second end; the seed light beam is output from the first end of the seed light source and the transmitted light beam is input from the first end of the seed light source;
and wherein he feedback loop external cavity further comprises:
a first collimation unit configured for collimating the seed light beam;
a unidirectional transmission unit configured for transmitting the seed light beam to the FP cavity, and blocking a reflection light beam of the FP cavity from being incident on the seed light source; and
a reflection unit configured for reflecting the transmitted light beam of the FP cavity back to the seed light source to form a feedback light path.

8. The frequency-modulated external cavity laser device according to claim 7, wherein the first collimation unit comprises a first lens; the unidirectional transmission unit comprises a polarizing beam splitter, a first quarter-wave plate, a second quarter-wave plate and a second lens in sequence; the reflection unit comprises a first reflection mirror; and
the FP cavity is located between the first quarter-wave plate and the second quarter-wave plate; and the second lens is located between the FP cavity and the second quarter-wave plate or between the second quarter-wave plate and the first reflection mirror.

9. The frequency-modulated external cavity laser device according to claim 1, wherein the seed light source comprises a first end and a second end; the seed light beam is output from a first end of the seed light source, and the transmitted light beam is input from the first end of the seed light source; or, the seed light beam is output from the first end of the seed light source, and the transmitted light beam is input from the second end of the seed light source; and
the feedback loop external cavity further comprises the unidirectional transmission unit and a light ray steering unit;
the unidirectional transmission unit is configured for transmitting the seed light beam to the FP cavity, and blocking a reflection light beam of the FP cavity from being incident on the seed light source; and
the light ray steering unit is configured for changing the transmission direction of the transmitted light beam of the FP cavity, so that the transmitted light beam is fed back to the seed light source to form a feedback light path.

10. The frequency-modulated external cavity laser device according to claim 9, wherein the unidirectional transmission unit comprises a circulator, and the light ray steering unit comprises a second reflection mirror, a third reflection mirror and a fourth reflection mirror;
wherein the light beam transmission path in the frequency-modulated external cavity laser device is as follows: the seed light beam is output from a first end of the seed light source, input from a first end of the circulator, output from a second end of the circulator, and is incident on the FP cavity for transmission to form the transmitted light beam; and the transmitted light beam is incident on a third end of the circulator after being reflected by the second reflection mirror, the third reflection mirror and the fourth reflection mirror in sequence, and is output from a first end of the circulator and fed back to the seed light source.

11. The frequency-modulated external cavity laser device according to claim 9, wherein the unidirectional transmission unit comprises an isolator, and the light ray steering unit comprises a fifth reflection mirror, a sixth reflection mirror, a seventh reflection mirror and an eighth reflection mirror;
wherein the light beam transmission path in the frequency-modulated external cavity laser device is as follows: the seed light beam is output from a first end of the seed light source, input from a first end of the isolator, output from a second end of the isolator, and is incident on the FP cavity for transmission to form the transmitted light beam; and the transmitted light beam is incident on a second end of the seed light source after being reflected by the fifth reflection mirror, the sixth reflection mirror, the seventh reflection mirror and the eighth reflection mirror in sequence.

12. The frequency-modulated external cavity laser device according to claim 7, wherein the unidirectional transmission unit further comprises at least one isolator, at least one of the isolators being located between the seed light source and the FP cavity.

13. The frequency-modulated external cavity laser device according to claim 1, wherein the FP cavity comprises a ninth reflection mirror and a tenth reflection mirror parallel to each other, and the seed light beam is incident by the ninth reflection mirror and is emergent by the tenth reflection mirror.

14. The frequency-modulated external cavity laser device according to claim 1, wherein the FP cavity comprises an eleventh reflection mirror, a twelfth reflection mirror and a thirteenth reflection mirror; and the seed light beam is incident by the eleventh reflection mirror, reflected by the twelfth reflection mirror and the thirteenth reflection mirror in sequence, and then emergent by the eleventh reflection mirror.

15. The frequency-modulated external cavity laser device according to claim 1, wherein the seed light source comprises a semiconductor laser.

16. The frequency-modulated external cavity laser device according to claim 1, wherein the seed light source comprises a combination of a gain chip and an optical filter, the optical filter being located at any position in the feedback loop external cavity.
